(19) United States
(12) Patent Application Publication
(10) Pub. No.: US 2006/0292847 A1
(43) Pub. Date: Dec. 28, 2006

(54) Silver barrier layers to minimize whisker growth in tin electrodeposits

(76) Inventor: Robert A. Schetty III, Laurel Hollow, NY (US)

Correspondence Address: WINSTON & STRAWN LLP;PATENT DEPARTMENT, 1700 K STREET, N.W., WASHINGTON, DC, 20006, US

(21) Appl. No.: 11/473,401

(22) Filed: Jun. 23, 2006

Related U.S. Application Data
(60) Provisional application No. 60/693,701, filed on Jun. 24, 2005.

(51) Int. Cl. H01L 21/66; H01L 21/44

(52) U.S. Cl. 438/597; 438/14

(57) ABSTRACT

The invention relates to a method of reducing tin whisker formation in a plated substrate that includes a surface layer comprising tin. The method includes providing on electroplatable portions of the substrate (a) an underlayer comprising silver or (b) a barrier layer that passes a mechanical load test when the surface layer, after 48 hours of contact with a 1 mm hemispherical tip that carries a load of between 500 to 2000 g, exhibits no whiskers having a length of greater than 5 microns. The underlayer or barrier layer, whichever is present, is provided in a thickness sufficient to prevent formation of intermetallic compounds between the substrate and surface layer so that the surface layer exhibits reduced whisker formation compared to the same surface layer deposited directly upon the substrate. Typically, the underlayer or barrier layer includes 50 to 100% by weight silver or similar ductile material.

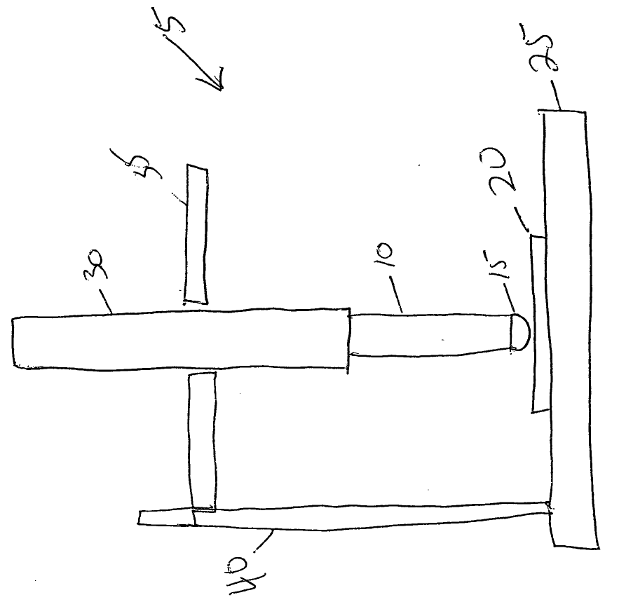

This application claims the benefit of U.S. provisional application 60/693,701 filed Jun. 24, 2005, the entire content of which is expressly incorporated herein by reference thereto.

### FIELD OF INVENTION

The present invention relates to a method for depositing tin in a manner to reduce, minimize or prevent tin whisker growth from such deposits, as well as to electroplated components formed by such a method. More particularly, the invention relates to the use of silver or silver alloy as a deposition layer underneath the tin deposit (“underlayer material”) to minimize tin whisker growth.

### BACKGROUND OF THE INVENTION

The use of a tin or tin alloy electroplated deposit has become increasingly important in fabricating electronic circuits, electronic devices and electrical connectors because of the benefits that such deposits provide. For example, tin and tin alloy deposits protect the components from corrosion, provide a chemically stable surface for soldering and maintain good surface electrical contact. There are many patents that disclose how to apply tin or tin alloy deposits using a variety of plating solutions and methods. Such deposits are typically produced by electroless plating or electroplating.

Regardless of the deposition process employed, it is desirable to form smooth and level deposits of tin on the substrate in order to minimize porosity. It is also desirable to form a coating having a relatively constant thickness in order to facilitate downstream component assembly operations. Furthermore, other problems must be avoided in order to obtain an acceptable deposit. When pure tin is used and is applied to a copper or copper alloy substrate, the resulting deposit suffers from interdiffusion of base material copper into the tin deposit and subsequent formation of copper-tin intermetallic compounds. While these copper-tin compounds can be brittle and may impair the usefulness of the tin coated component, their presence also results in compressive stress formation in the tin deposit. Subsequently, the generation of metal filaments known as tin whiskers sometimes grow spontaneously from these tin deposits. These whiskers are hair-like projections extending from the surface and may be either straight or curled or bent. Tin whiskers typically have a diameter of about 6 nanometers to 6 microns. The presence of such whiskers is undesirable due to the very fine line definition required for modern circuitry, since these whiskers can form both electrical shorts and electrical bridges across insulation spaces between conductors. The whiskers may create shorts or introduce failures into electronic circuitry.

The mechanism of tin whisker growth is not fully understood. The whiskers can begin to grow within days of the application of the coating or even several years thereafter. There is speculation in the literature that the whiskers grow from compressive stress concentration sites, such as those created through many electrodeposition techniques and/or storage conditions. There is evidence that elevated temperature and humidity storage conditions enhance whisker growth. The article “Simultaneous Growth of Whiskers on Tin Coatings: 20 Years of Observation”, by S. C. Britton, Transactions of the Institute of Metal Finishing, Volume 52, 1974, pp. 95-102 discusses the tin whisker growth problem and offers several recommendations for reducing the risk of whisker formation.

One approach for addressing the tin whisker problem has been to specify short storage times for tin plated materials. However, this approach does not fully address or necessarily avoid the problem. Another approach has been to mildly strengthen the tin matrix to prevent extrusion of the whiskers. The formation of an intermetallic compound and diffusion of copper into the tin deposit have served this purpose but at prohibitive performance cost in the final product.

Another approach is to treat the surface of the substrate before applying the tin deposit. Ultrasonic agitation of the plating solution and/or alternating the polarity of the electrodes during plating have been suggested to reduce the amount of hydrogen absorbed or occluded in the structure of the plating metal.

Additional approaches for dealing with this problem have generally involved a whisker inhibiting element addition to the tin plating solution. In order to avoid the high cost of precious metals, the most common approach has been to deposit an alloy of tin and lead. This alloy is also compatible with the solders that are later used to make electrical connections to wires or other electrical components. Unfortunately, lead and a number of other alloying elements are undesirable due to their toxicity and related environmental issues.

Recent publications have indicated that tin deposited over copper/copper alloy substrates generally start out with no or slightly low compressive stress as-plated, but during deposit aging compressive stress in the tin deposit increases significantly. It is theorized that this increase in compressive stress is due to diffusion of copper from the base material into the tin deposit and the subsequent formation of copper-tin intermetallic compounds; the accompanying volume transformation which occurs in turn generates the compressive stress that results in tin whisker formation.

One method to counter-act this series of events described in the aforementioned paragraph would be to deposit another material (“underlayer”) between the tin deposit and the substrate to function as a “barrier” layer. This underlying barrier layer physically blocks the copper/copper alloy base material elements from diffusing into the overlying tin deposit and therefore avoids copper tin intermetallic compound formation which in turn eliminates the driving force for tin whisker growth. The use of a nickel deposit as an effective barrier for minimizing tin whisker formation was first disclosed by R. Schetty in the article “Minimization of Tin Whisker Formation for Lead-Free Electronics Finishing” from the IPC Works conference proceedings of September 2000. U.S. Patent Application No. 20020187364 A1 also describes such a method using nickel as the barrier layer between the tin deposit and the substrate to minimize tin whisker growth.

While nickel is effective as a barrier layer to prevent copper diffusion, it also has significant disadvantages. For example, most electronic components are subjected to mechanical deformation during assembly operations which occur after the tin layer is deposited such as the trim/form operation for semiconductor components in which the metallized component leads are bent as much as 90° or more. Since the ductility values of the copper substrate and tin deposit (typically >>30%) are much higher than the ductility of the nickel deposit (typically <20%), the nickel deposit will often experience cracking during the aforementioned assembly operations. The cracks in the nickel deposit will propagate upwards to the surface of the overlying tin deposit and downwards to the copper/copper alloy substrate. The nickel cracking phenomenon not only exposes base material copper to the tin deposit which effectively negates its effectiveness as a barrier layer for tin whisker minimization, it also exposes the copper substrate to the atmosphere which results in oxidation of the substrate and poor solderability performance, effectively negating the originally intended function of the overlying tin deposit which is to prevent oxidation of the substrate and make the component solderable.

A further disadvantage of the nickel barrier layer is that its application requires substantial modification to existing plating lines which are currently not set-up for nickel plating. This incurs a significant increase in capital cost (plating equipment, floor space, etc.) and increased running cost (nickel plating chemistry and associated pre-treatment & post-treatment processes, waste treatment costs, etc.) for the electronic component manufacturer which is obviously undesirable.

One additional disadvantage of the nickel barrier layer is the fact that the coefficient of thermal expansion (CTE) value of nickel is relatively low (CTE<10 ppm/° K) and dissimilar in value compared to copper(CTE=17 ppm/°K) and tin (CTE=23 ppm/° K) which have relatively high CTE values and are very similar in value to each other. Materials with dissimilar CTE values are known to expand and contract at different rates when exposed to heating (expansion) or cooling (contraction) accordingly. One of the common accelerated tin whisker test methods involves thermal cycling of the plated component between a large temperature range for an extended number of cycles. For example, the electronics industry standard for tin whisker testing methods, JEDEC STANDARD JESD22A121 “Measuring Whisker Growth on Tin and Tin Alloy Surface Finishes”, specifies thermal cycling of a component from −40° C. (or −55° C.) to +85° C. for 1000 cycles. Studies have been published indicating the dissimilar CTE values of nickel vs. tin and copper induce a compressive stress in the tin deposit caused by the different rates of expansion/contraction during thermal cycling of the nickel, copper, and tin which in turn generates tin whisker growth. This phenomenon is referred to in the industry as “CTE mis-match”. Since copper and tin have similar CTE values, there is no CTE mis-match and these materials expand and contract at similar rates during thermal cycling and so compressive stress generation in the case of tin deposited directly over nickel (i.e., absence of a nickel barrier layer) is minimal. In this case, the nickel barrier is in fact detrimental to tin whisker growth propensity, defeating the entire purpose of its intended function.

In summary, it would be beneficial to identify a barrier layer which could be applied to a copper/copper alloy substrate as an underlayer to the overlying tin deposit to minimize diffusion of base metal elements into the tin deposit which does not exhibit such disadvantages as those mentioned above. The present invention provides such a method and is provided herewith.

### SUMMARY OF THE INVENTION

The invention relates to a method of reducing tin whisker formation in a plated substrate that includes a surface layer comprising tin. The method comprises providing on electroplatable portions of the substrate (a) an underlayer comprising silver or (b) a barrier layer that passes a mechanical load test that requires the surface layer, after 48 hours of contact with a 1 mm hemispherical tip that carries a load of between 500 to 2000 g, to exhibit no whiskers having a length of greater than 5 microns. The underlayer or barrier layer, whichever is present, is provided in a thickness sufficient to prevent formation of intermetallic compounds between the substrate and surface layer so that the surface layer exhibits reduced whisker formation compared to the same surface layer deposited directly upon the substrate.

In this method, the underlayer or barrier layer advantageously has a thickness of about 0.05 to 2 microns. The underlayer or barrier layer preferably comprises greater than 50% to 100% by weight silver and may be provided by electroless or electrolytic plating. Also, the surface layer includes at least 95 to 99% by weight tin and is typically provided by electroplating. The optimum substrates for use in the invention are electronic components that also include non-electroplatable portions. For these substrates, the underlayer or barrier layer is provided only upon the electroplatable portions and the surface layer is provided only on the underlayer or barrier layer. It is these substrates that are susceptible to tin whiskering and that are in the greatest need of reducing or eliminating tin whiskering to avoid short circuits or other undesired electrical inconsistencies in the final product.

Another embodiment of the invention relates to a plated substrate comprising a substrate having electroplatable portions, either (a) an underlayer comprising silver or (b) a barrier layer that passes a mechanical load test on the electroplatable portions of the substrate; and a surface layer comprising tin on the underlayer or barrier layer. The mechanical load test is the same as that described above and the thickness of the underlayer or barrier layer, whichever is present, is sufficient so that the surface layer exhibits reduced whisker formation compared to the same surface layer deposited directly upon the substrate. The invention also relates to a method for making a plated substrate that has reduced tin whisker formation, which comprises providing on electroplatable portions of the substrate (a) an underlayer comprising silver or (b) a barrier layer that passes a mechanical load test as mentioned above; and depositing a surface layer comprising tin upon the underlayer or barrier layer o the type mentioned above.

Yet another embodiment of the invention is a new and more stringent method for predicting whisker formation in a surface layer comprising tin associated with a substrate, which comprises subjecting the substrate to a mechanical load test that includes 48 hours of contact of the surface layer with a 1 mm hemispherical tip that carries a load of between 500 to 2000 g; and measuring tin whisker length, if any, after the 48 hours contact time. The surface layer passes the test if it exhibits no whiskers having a length of greater than 5 microns. The greater the load, the more stringent the test. This method is helpful for selecting the best tin deposits for critical or high quality applications. As noted above, an underlayer or barrier layer of a ductile material, preferably one that includes more than 50% by weight silver, is useful in enabling the plated substrate to pass this stringent test.

### BRIEF DESCRIPTION OF THE DRAWING

The appended drawing figure is a schematic illustration of a mechanical load test that can be used to determine potential of tin whisker formation in plated substrates that include a surface layer comprising tin.

### DETAILED DESCRIPTION OF THE PREFERRED EMBODIMENTS

The present invention relates to a method of reducing tin whiskers on substrates by first depositing an underlayer or barrier layer of a material that typically includes silver or a silver alloy prior to depositing a layer of tin or tin alloy over the underlayer. The invention also relates to substrates and electronic components formed according to this method.

It has been found that the use of certain particular barrier layers or underlayers impart highly enhanced reductions or complete elimination of tin whisker formation in surface layers that include tin. The ideal material for such a layer is a ductile, relatively low cost, commonly available material so that the whiskering problem is resolved simply and elegantly. In this specification, the terms “barrier layer” and “underlayer” are used interchangeably, since each is provided between the surface layer and the electroplatable portions of the substrate at a thickness sufficient to prevent the formation of intermetallic compounds between the substrate and the tin containing surface layer. Such compounds are also believed to be a source of tin whiskering. These layers also reduce stress in the surface layer.

Suitable underlayers useful with the present invention include silver and silver alloys which may include silver-tin, silver-palladium, or silver with other alloying elements. Since the ductility of silver (typically >70%) is much greater than that of tin (typically >30%), the silver deposit does not exhibit cracking during assembly operations such as trim and form of semiconductor components. It is believed that this high ductility contributes to the prevention or reduction of whiskering as it is able to absorb stresses in the tin deposit and offset the stress in the tin deposit that can lead to tin whiskering.

Furthermore, the use of silver as a barrier layer effectively resolves other detrimental issues associated with nickel barrier layers (i.e., incurring additional process steps and increased costs to manufacturers) as follows: Silver is today typically plated selectively on the electronic component substrate (“lead frame”) prior to tin plating as part of the standard manufacturing process, since silver is currently the most common material used for attachment of the semiconductor chip or “die” to the substrate as well as the associated wire bonds which form the interconnection from the die to the component terminations. Since the preferred embodiment of this invention involves relatively thin (<1 micron) silver deposit thickness, also commonly referred to as a “silver flash” deposit, it would be extremely simple and straightforward for the lead frame manufacturer to apply a silver deposit non-selectively, i.e., across the entire component lead frame substrate surface, during the normal course of manufacture, at little to no additional cost to the electronic component manufacturer.

In an alternate variation of the present invention, if the lead frame component substrate manufacturer is unable or unwilling to apply the silver deposit and the substrate is delivered to the electronic component manufacturer without the overall silver deposit on the substrate, it is relatively easy and straightforward for the electronic component manufacturer to incorporate a silver “flash” or immersion plating process into the existing tin/tin alloy plating line with relatively simple modifications to existing equipment and/or process flow. Notwithstanding the fact that silver is a precious metal, since the preferred embodiment of this invention involves relatively thin coatings, the additional costs incurred to apply such thin “flash” deposits of silver would be minimal.

As the CTE value of silver is 19 ppm/° K which is similar to copper (CTE=17 ppm/° K) and tin (CTE=23 ppm/° K), there is no CTE mis-match issue during thermal cycling with silver as a barrier layer. Thus the CTE mis-match issue experienced when using a nickel barrier layer is fully resolved when implementing silver as an underlayer to minimize tin whisker growth propensity.

The underlayers or barrier layers of the present invention may be deposited by a variety of methods. Such methods may include electroless plating, electrolytic plating, immersion plating, or chemical or physical vapor deposition. Preferably, the underlayer or barrier layer is deposited by electroless or electrolytic plating with the selection of the appropriate plating system being made based on the preferences of the electroplater. The choice of deposition technique also will vary based on the nature of the substrate and the nature of the specific silver or silver alloy layer to be deposited.

Any suitable silver plating solution may be used. The type of method or solution used to provide the silver deposit is not critical, provided that a layer of sufficient thickness is deposited to function as a barrier layer between reduce tensile stress in the tin deposit. For example, suitable plating solutions include the immersion silver baths known as Argentomerse, available from Technic, Inc. of Cranston, R.I., but any other suitable immersion silver solution that is compatible with the substrates to be plated would be suitable. A silver cyanide electrolyte such as Techni Silver EHS-3, also available from Technic, Inc., may instead be used. In general, any non non-cyanide silver cyanide organometallic complex bath can be used. For example, a phosphate boric acid bath such as the type known as Silverjet 2 and previously available from LeaRonal Inc., or an equivalent formulation, is suitable, as are the well known succinimide based non-cyanide baths of the prior art, such as U.S. Pat. No. 4,246,077. A preferred silver electroplating bath is disclosed in U.S. patent application Ser. No. 10/785,297 filed Feb. 24, 2004, the entire content of which is expressly incorporated herein by reference thereto. The bath chemistries of U.S. Pat. Nos. 4,126,524, 4,426,671, 4,478,691, or 5,601,696 can also be used, if desired.

In a preferred embodiment, the underlayer or barrier layer has a thickness of about 0.15 micron and a silver content that is greater than 80% by weight of the deposit.

To determine whether or not a particular barrier layer is suitable for preventing or sufficiently reducing tin whiskering, a Mechanical loading test has been developed. This test identifies the most desirable barrier layers and is intended to be used for applications where essentially no tin whiskering can be tolerated. Such applications include those where extremely small electrical components are utilized, and in particular those having electroplatable and non-electroplatable portions. In such component, any appreciable tin whiskering can lead to short circuits and other improper performance of the components with the reliability of the final product being compromised. The present mechanical load test has been found to differentiate between the marginal performers and those barrier layers that enhance the surface layer so that essentially no tin whiskering at all is exhibited when necessary for applications that require the greatest reliability.

The drawing figure illustrates this test. As shown in schematic form, the testing device 5 includes a shaft 10 that includes a tip 15 of a 1 mm hemispherical ball of ruby or stainless steel is provided at the end of the shaft. The shaft length is not critical but may be in the range of 40 to 250 mm. A longer length is useful since it is easier to maintain the shaft in a perpendicular orientation upon the plated substrate 20. The plated substrate 20 is placed upon a support or base 25 that can be set up on a table or other flat and vibration free surface. If desired, a dampening pad of a foam, an elastomer or a padded fabric can be provided beneath the base to prevent vibrations from being imparted to the substrate and tip. The shaft 10 is secured to am extension 30 that provides a weight in the range of 500 to 2000 g. A threaded connection is suitable as is any other technique for adhering the shaft 10 to the extension. The extension 30 can be a solid or hollow tube or cylinder that is filled with metal pellets, water or other material to attain the desired weight. The shaft 10 or extension 30 can be held upright by the use of an acrylic plate 35 having a hole that is has a diameter that is slightly larger than the diameter of the shaft 10 or extension 30. The plate 35 is held at the desired height by operative association with a rod 40 that extends vertically from the base 25. Instead of plate 35, clamps or other holding devices can be used to maintain the shaft and extension in a vertical position with the tip in contact with the surface layer of the plated substrate 20. This substrate is a rectangular or square plate that includes the barrier layer and surface layer thereon in the same thickness that is intended for plating on the electrical components or other parts that are to be commercially produced. The tip remains in contact with the surface layer for a preselected time period. 48 hours have been found to be sufficient to generate tin whiskers in surface layers that are prone to this problem. The higher weights can be used with longer times when greater stringency of the test is required.

After the test time is over, the sample is removed and observed with an optical microscope or scanning electron microscope. Samples are considered to have passed the test when no whiskers having a length of greater than 5 microns are found in the sample. The tip produces an indentation in the surface layer of the sample and tin whiskering, if it is to be found, occurs around the circumference of the indentation. This test has been found to be relatively simple to implement and rather difficult to pass. The end user can be confident that samples that pass the test will provide a high level of reliability when electronic components that are plated with the barrier and surface layers are placed into service.

This mechanical load test was developed in response to industry observations that tin plated electronic components that are subject to mechanical loads, such as crimping or other compressions, are more likely to exhibit tin whiskering. This test provides an approximation of such loads and in turn is a reliable indicator of what one can expect from a particular tin plating when exposed to such mechanical loads.

The tin plating solutions that are useful in the present invention include, but are not limited to those described below:

FLUOBORATE SOLUTIONS: Tin fluoborate plating baths are widely used for plating all types of metal substrates including both copper and iron. See for example, U.S. Pat. Nos. 5,431,805, 4,029,556 and 3,770,599. These baths are preferred where plating speed is important and the fluoborate salts are very soluble.

HALIDE SOLUTIONS: Tin plating baths with the main electrolyte being a halide ion (Br, Cl, F, I) have been used for many decades. See for example, U.S. Pat. Nos. 5,628,893 and 5,538,617. The primary halide ions in these baths have been chloride and fluoride.

SULFATE SOLUTIONS: Tin and tin alloys are commercially plated from solutions with sulfate as the primary anion. See for example U.S. Pat. Nos. 4,347,107, 4,331,518 and 3,616,306. For example the steel industry has been tin plating steel for many years from sulfuric acid/tin sulfate baths where phenol sulfonic acid is used as a special electrolyte additive which improves both the oxidative stability of the tin as well as increasing its current density range. This process, known as the ferrostan process, is usable in the present invention but is not preferred because of environmental problems with phenol derivatives. Other sulfate baths based on sulfuric acid but without environmentally undesirable additives are preferred.

SULFONIC ACID SOLUTIONS: In the last two decades the commercial use of sulfonic acid metal plating baths has increased considerably because of a number of performance advantages. Tin has been electroplated from sulfonic acid (see for example U.S. Pat. Nos. 6,132,348, 4,701,244 and 4,459,185. The cost of the alkyl sulfonic acid is relatively high, so that the preferred sulfonic acid used has been methane sulfonic acid (MSA) although the prior art includes examples of other alkyl and alkanol sulfonic acids. The performance advantages of alkyl sulfonic acid baths include low corrosivity, high solubility of salts, good conductivity, good oxidative stability of tine salts and complete biodegradability.

These solutions can be used alone or in various mixtures. One of ordinary skill in the art can best select the most preferred acid or acid mixture for any particular plating application.

The amount of tin (as tin metal) in the plating solutions of the present invention may be varied over a wide range such as from about 1 to about 120 grams of metal per liter of solution (g/l), or up to the solubility limit of the particular tin salt in the particular solution. It should be understood that the foregoing quantities of tin in the plating solution are disclosed as metallic tin, but that the tin may be added to the solutions in the form of tin compounds. Such compounds may include, for example, tin oxide, tin salts, or other soluble tin compounds, including formates, acetates, hydrochlorides and other halides, carbonates and the like.

Any one of a number of alloying elements can be added to the tin plating solution. These are primarily added in an amount such that less than 5% of the alloying element is present in the deposit. Preferred alloying elements include silver (up to 3.5% of the deposit), Bismuth (up to 3% of the deposit), copper (up to 3% of the deposit) and zinc (up to 2% of the deposit). While other alloying elements can be used, it is generally not preferred to use those that may have an adverse effect on the environment, i.e., antimony, cadmium, and particularly lead. Preferably, the tin content of the deposit is as high as possible and is usually on the order of as high as 99% by weight or more with the balance being unavoidable impurities rather than intentionally added alloying elements.

### EXAMPLES

The following examples illustrate the most preferred embodiments of the invention.

### Example (1)

Tin was electroplated from an MSA electrolyte onto a Cu alloy substrate (Cu99.85%, Sn0.15%) at a current density of 100 A/ft² for a period of time sufficient to obtain an average of 10 μm tin deposit thickness. The deposit was subjected to the three whisker test conditions specified by JEDEC STANDARD JESD22A121 “Measuring Whisker Growth on Tin and Tin Alloy Surface Finishes”, specifically: (i) thermal cycling −40° C. to +85° C. for 1000 cycles; (ii) ambient storage (30° C., 60% RH) for min. 3000 hrs; and (iii) high temperature/humidity storage (60° C./90% RH) for min. 3000 hrs. Upon completion of the whisker test method, the maximum whisker length was measured and determined to be 78 μm.

### Example (2)

Nickel barrier layer was plated from a commercial nickel sulfamate electrolyte (Techni Nickel FFP from Technic Inc.) onto a Cu alloy substrate (Cu99.85%, Sn0.15%) at a current density of 50 A/ft² for a period of time sufficient to obtain an average of 2 μm nickel deposit thickness, then tin was electroplated on the nickel barrier layer from an MSA electrolyte at a current density of 100 A/ft² for a period of time sufficient to obtain an average of 10 μm tin deposit thickness. The deposit was subjected to the three whisker test conditions specified by JEDEC STANDARD JESD22A121 “Measuring Whisker Growth on Tin and Tin Alloy Surface Finishes”, specifically: (i) thermal cycling −40° C. to +85° C. for 1000 cycles; (ii) ambient storage (30° C., 60% RH) for min. 3000 hrs; and (iii) high temperature/humidity storage (60° C./90% RH) for min. 3000 hrs. Upon completion of these whisker test methods, the maximum whisker length was measured and determined to be 55 μm.

### Example (3)

Silver barrier layer was plated from a commercial silver cyanide electrolyte (Techni Silver EHS-3 from Technic Inc.) onto a Cu alloy substrate (Cu99.85%, Sn0.15%) at a current density of 50 A/ft² for a period of time sufficient to obtain an average of 0.15 μm silver deposit thickness, then tin was electroplated on the silver barrier layer from an MSA electrolyte at a current density of 100 A/ft² for a period of time sufficient to obtain an average of 10 μm tin deposit thickness. The deposit was subjected to the three whisker test conditions specified by JEDEC STANDARD JESD22A121 “Measuring Whisker Growth on Tin and Tin Alloy Surface Finishes”, specifically: (i) thermal cycling −40° C. to +85° C. for 1000 cycles; (ii) ambient storage (30° C., 60% RH) for min. 3000 hrs; and (iii) high temperature/humidity storage (60° C./90% RH) for min. 3000 hrs. Upon completion of these whisker test methods, the maximum whisker length was measured and determined to be <5 μm.

### Example (4)

Silver barrier layer was plated from a commercial silver non-cyanide electrolyte (Techni Cyless II from Technic Inc.) onto a Cu alloy substrate (Cu99.85%, Sn0.15%) at a current density of 5 A/ft² for a period of time sufficient to obtain an average of 2 μm silver deposit thickness, then tin was electroplated on the silver barrier layer from an MSA electrolyte at a current density of 100 A/ft² for a period of time sufficient to obtain an average of 10 μm tin deposit thickness. The deposit was subjected to the three whisker test conditions specified by JEDEC STANDARD JESD22A121 “Measuring Whisker Growth on Tin and Tin Alloy Surface Finishes”, specifically: (i) thermal cycling −40° C. to +85° C. for 1000 cycles; (ii) ambient storage (30° C., 60% RH) for min. 3000 hrs; and (iii) high temperature/humidity storage (60° C./90% RH) for min. 3000 hrs. Upon completion of these whisker test methods, the maximum whisker length was measured and determined to be <5 μm.

### Example (5)

Tin was electroplated from a commercial mixed acid electrolyte (Technistan EP from Technic Inc.) onto a Cu alloy substrate (Cu99.85%, Sn0.15%) at a current density of 100 A/ft² for a period of time sufficient to obtain an average of 10 μm tin deposit thickness. The deposit was subjected to the three whisker test conditions specified by JEDEC STANDARD JESD22A121 “Measuring Whisker Growth on Tin and Tin Alloy Surface Finishes”, specifically: (i) thermal cycling −40° C. to +8° C. for 1000 cycles; (ii) ambient storage (30° C., 60 % RH) for min. 3000 hrs; and (iii) high temperature/humidity storage (60° C./90% RH) for min. 3000 hrs. Upon completion of the whisker test method, the maximum whisker length was measured and determined to be 35 μm.

### Example (6)

Silver barrier layer was plated from a commercial silver cyanide electrolyte (Techni Silver EHS-3 from Technic Inc.) onto a Cu alloy substrate (Cu99.85%, Sn0.15%) at a current density of 50 A/ft² for a period of time sufficient to obtain an average of 0.15 μm silver deposit thickness, then tin was electroplated on the silver barrier layer from a commercial mixed acid electrolyte (Technistan EP from Technic Inc.) at a current density of 100 A/ft² for a period of time sufficient to obtain an average of 10 μm tin deposit thickness. The deposit was subjected to the three whisker test conditions specified by JEDEC STANDARD JESD22A121 “Measuring Whisker Growth on Tin and Tin Alloy Surface Finishes”, specifically: (i) thermal cycling −40° C. to +85° C. for 1000 cycles; (ii) ambient storage (30° C., 60% RH) for min. 3000 hrs; and (iii) high temperature/humidity storage (60° C./90% RH) for min. 3000 hrs. Upon completion of these whisker test methods, the maximum whisker length was measured and determined to be <5 μm.

### Example (7)

Silver barrier layer was plated from a commercial silver cyanide electrolyte (Techni Silver EHS-3 from Technic Inc.) onto a Cu alloy substrate (Cu99.85%, Sn0.15%) at a current density of 50 A/ft² for a period of time sufficient to obtain an average of 0.15 μm silver deposit thickness, then tin was electroplated on the silver barrier layer from a commercial mixed acid electrolyte (Technistan EP from Technic Inc.) at a current density of 100 A/ft² for a period of time sufficient to obtain an average of 4 μm tin deposit thickness. The deposit was subjected to the three whisker test conditions specified by JEDEC STANDARD JESD22A121 “Measuring Whisker Growth on Tin and Tin Alloy Surface Finishes”, specifically: (i) thermal cycling −40° C. to +85° C. for 1000 cycles; (ii) ambient storage (30° C., 60% RH) for min. 3000 hrs; and (iii) high temperature/humidity storage (60° C./90% RH) for min. 3000 hrs. Upon completion of these whisker test methods, the maximum whisker length was measured and determined to be <5 μm.

### Example (8)

Tin was electroplated from an MSA electrolyte onto a Cu alloy substrate (Cu99.85%, Sn0.15%) at a current density of 100 A/ft² for a period of time sufficient to obtain an average of 10 μm tin deposit thickness. The deposit was subjected to the mechanical load whisker test described previously for 48 hrs. Upon completion of the whisker test method, the maximum whisker length was measured and determined to be 110 μm.

### Example (9) Nickel barrier layer was plated from a commercial nickel sulfamate electrolyte

(Techni Nickel FFP from Technic Inc.) onto a Cu alloy substrate (Cu99.85%, Sn0.15%) at a current density of 50 A/ft² for a period of time sufficient to obtain an average of 2 μm nickel deposit thickness, then tin was electroplated on the nickel barrier layer from an MSA electrolyte at a current density of 100 A/ft² for a period of time sufficient to obtain an average of 10 μm tin deposit thickness. The deposit was subjected to the mechanical load whisker test described previously for 48 hrs. Upon completion of the whisker test method, the maximum whisker length was measured and determined to be 122 μm.

### Example (10)

Silver barrier layer was plated from a commercial silver cyanide electrolyte (Techni Silver EHS-3 from Technic Inc.) onto a Cu alloy substrate (Cu99.85%, Sn0.15%) at a current density of 50 A/ft² for a period of time sufficient to obtain an average of 0.15 μm silver deposit thickness, then tin was electroplated on the silver barrier layer from an MSA electrolyte at a current density of 100 A/ft² for a period of time sufficient to obtain an average of 10 μm tin deposit thickness. The deposit was subjected to the mechanical load whisker test described previously for 48 hrs. Upon completion of the whisker test method, the maximum whisker length was measured and determined to be <5 μm.

### Example (11)

Silver barrier layer was plated from a commercial silver cyanide electrolyte (Techni Silver EHS-3 from Technic Inc.) onto a Cu alloy substrate (Cu99.85%, Sn0.15%) at a current density of 50 A/ft² for a period of time sufficient to obtain an average of 0.15 μm silver deposit thickness, then tin was electroplated on the silver barrier layer from an MSA electrolyte at a current density of 100 A/ft² for a period of time sufficient to obtain an average of 10 μm tin deposit thickness. The electroplated part was then subjected to reflow in a convection oven at 280 deg C for 3 min. The reflowed deposit was then subjected to the mechanical load whisker test described previously for 48 hrs. Upon completion of the whisker test method, the maximum whisker length was measured and determined to be <2 μm.

What is claimed is:

1. A method for reducing tin whisker formation in a plated substrate that includes a surface layer comprising tin, which comprises providing on electroplatable portions of the substrate (a) an underlayer comprising silver or (b) a barrier layer that passes a mechanical load test that requires the surface layer, after 48 hours of contact with a 1 mm hemispherical tip that carries a load of between 500 to 2000 g, to exhibit no whiskers having a length of greater than 5 microns; wherein the underlayer or barrier layer, whichever is present, is provided in a thickness sufficient to prevent formation of intermetallic compounds between the substrate and surface layer or to reduce stress in the surface layer so that the surface layer exhibits reduced whisker formation compared to the same surface layer deposited directly upon the substrate.

2. The method of claim 1, wherein the underlayer or barrier layer has a thickness of about 0.05 to 2 microns.

3. The method of claim 1, wherein the underlayer or barrier layer comprises greater than 50% to 100% by weight silver and is provided by electroless or electrolytic plating.

4. The method of claim 1, wherein the surface layer includes at least 95 to 99% by weight tin and provided by electroplating.

5. The method of claim 1, wherein the substrate is an electronic component that also includes non-electroplatable portions and the underlayer or barrier layer is provided only upon the electroplatable portions.

6. A plated substrate comprising:
a substrate having electroplatable portions,
either (a) an underlayer comprising silver or (b) a barrier layer that passes a mechanical load test on the electroplatable portions of the substrate; and
a surface layer comprising tin on the underlayer or barrier layer;
wherein the barrier layer passes the mechanical load test that requires the surface layer, after 48 hours of contact with a 1 mm hemispherical tip that carries a load of between 500 to 2000 g, to exhibit no whiskers having a length of greater than 5 microns; and
wherein the underlayer or barrier layer, whichever is present, is provided in a thickness sufficient to prevent formation of intermetallic compounds between the substrate and surface layer or to reduce stress in the surface layer so that the surface layer exhibits reduced whisker formation compared to the same surface layer deposited directly upon the substrate.

7. The plated substrate of claim 6, wherein the underlayer or barrier layer has a thickness of about 0.05 to 2 microns.

8. The plated substrate of claim 6, wherein the underlayer or barrier layer comprises greater than 50% to 100% by weight silver.

9. The plated substrate of claim 6, wherein the surface layer includes at least 95 and 99% by weight tin.

10. The plated substrate of claim 6, wherein the substrate is an electronic component that also includes non-electroplatable portions and the underlayer or barrier layer is provided only upon the electroplatable portions.

11. A method for making a plated substrate that has reduced tin whisker formation, which comprises:
providing on electroplatable portions of the substrate (a) an underlayer comprising silver or (b) a barrier layer that passes a mechanical load test; and
depositing a surface layer comprising tin upon the underlayer or barrier layer;
wherein the barrier layer passes the mechanical test that requires the surface layer, after 48 hours of contact with a 1 mm hemispherical tip that carries a load of between 500 to 2000 g, to exhibit no whiskers having a length of greater than 5 microns; and
wherein the underlayer or barrier layer, whichever is present, is provided in a thickness sufficient to prevent formation of intermetallic compounds between the substrate and surface layer or to reduce stress in the surface layer so that the surface layer exhibits reduced whisker formation compared to the same surface layer deposited directly upon the substrate.

12. The method of claim 11, wherein the underlayer or barrier layer has a thickness of about 0.05 to 2 microns.

13. The method of claim 11, wherein the underlayer or barrier layer comprises greater than 50% to 100% by weight silver and is provided by electroless or electrolytic plating.

14. The method of claim 11, wherein the surface layer includes at least 95 to 99% by weight tin and provided by electroplating.

15. The method of claim 11, wherein the substrate is an electronic component that also includes non-electroplatable portions and the underlayer or barrier layer is provided only upon the electroplatable portions.

16. A method for predicting whisker formation in a surface layer comprising tin associated with a substrate, which comprises:
subjecting the substrate to a mechanical load test that includes 48 hours of contact of the surface layer with a 1 mm hemispherical tip that carries a load of between 500 to 2000 g; and
measuring tin whisker length, if any, after the 48 hours contact time,
wherein the surface layer passes the test if it exhibits no whiskers having a length of greater than 5 microns.

17. The method of claim 16 wherein the plated substrate includes an underlayer or barrier layer of a sufficiently ductile material to be able to pass the test.
